(19) United States
(12) Patent Application Publication
(10) Pub. No.: US 2021/0071009 A1
(43) Pub. Date: Mar. 11, 2021

(54) OBJECT WITH A HIGH-TEMPERATURE-RESISTANT OMNIPHOBIC NON-STICK COATING, AND METHOD FOR PRODUCING SUCH AN OBJECT

(71) Applicant: BSH Hausgeräte GmbH, Munich (DE)

(72) Inventors: Frank JÖRDENS, Traunstein (DE); Carmen MARSCHNER, Jena (DE); Andreas PFUCH, Apolda (DE); Jürgen SALOMON, Trostberg (DE); Gerhard SCHMIDMAYER, Bad Endorf (DE); Tina TÖLKE, Saalfeld/ Saale (DE)

(21) Appl. No.: 16/772,202

(22) PCT Filed: Nov. 23, 2018
(86) PCT No.: PCT/EP2018/082347

§ 371 Date: Jun. 12, 2020

(30) Foreign Application Priority Data
Dec. 22, 2017 (DE) 10 2017 223 680.9

(51) Int. Cl. C09D 5/00; C23C 16/02; C23C 16/50; C23C 16/40; C09D 183/04; C09D 7/61

(52) U.S. Cl. CPC C09D 5/002; C23C 16/0227; C23C 16/50; C09D 7/61; C23C 16/402; C09D 183/04; C23C 16/0272

(57) ABSTRACT

An object having a high temperature resistance includes an inorganic substrate, an omniphobic non-stick coating, and an adhesion-promoting coating containing amorphic silicon dioxide and located between the inorganic substrate and the omniphobic non-stick coating.

The present invention relates to an object with a high-temperature-resistant omniphobic non-stick coating that is scratch-resistant and easy to clean, and also a method for producing the object.

### PRIOR ART

Temperature-resistant, scratch-resistant non-stick coatings for substrates of glass or enamel that for parts of household appliances such as cooking appliances (inter alia for glass ceramic hobs or interior components of ovens or microwaves for example) that are heated or come into contact with heated foodstuffs, are generally known. These coatings may be applied to the surface that is to be coated for example via a sol-gel method. Furthermore, these coatings may be omniphobic, in other words they may comprise both hydrophobic as well as oleophobic properties in order to improve the cleaning capability with respect to foodstuff residues for example.

WO 99/02463 discloses temperature-resistant and scratch-resistant non-stick coatings that are applied using a single stage sol-gel method. According to WO 99/02463, the coatings are temperature resistant up to >500° C. Tests have however shown that these coatings are only resistant up to a maximum of 300° C. over a longer period of time and an increase of the surface energy occurs at temperatures greater than 300° C. within a short period of time. This in turn causes a deterioration of the cleaning capability of burnt-in foodstuff residues for example and leads to a pronounced tendency to spot. Consequently, the high-temperature-resistance of these coatings is insufficient.

Furthermore, coatings that contain nanoparticles for improving the scratch-resistance, such as for example the “Nanoclean” coatings from the company PEMCO, are known. In accordance with “Schlegel, C.: “Glassy Surface Functionalisation by Nano-modified sol-gel Technology”, XXI International Enamellers Congress, May 18, 2008, pages 41-50, XP002599577″ these Nanoclean coatings are sol-gel coatings that are modified with nanoparticles in which in embodiments an application of a SiOₓ intermediate coating is provided via a preceding flame treatment and silanization. These coatings are however only heat-resistant up to a maximum of 300° C.

EP2281916 A1 and DE102009030876 A1 disclose two-stage coating methods of substrates so that a silicon dioxide coating is obtained as an adhesion-promoting coating that is applied via an atmospheric pressure process, and a further coating is obtained that is applied via a wet-chemical process. These methods however require the preceding application of a primer to the substrate in order to ensure the desired adhesion. Furthermore, the temperature resistance of these coatings is insufficient.

In particular against the background that cooking appliances are exposed to ever higher temperatures, since for example ovens are able to be heated ever more rapidly with the result that, depending upon the process, in general temperatures of 350° C. or higher are achieved, the requirements for the coatings also increase in relation to their temperature-resistance.

However, in the prior art there are no known omniphobic non-stick coatings for glass substrates or enamel substrates for example, which have a high scratch-resistance and therefore an easy cleaning capability even after a high temperature treatment of for example greater than 350° C. over a longer period of time, in other words there is the requirement for objects with omniphobic non-stick coatings that are in particular resistant to temperatures of 350° C. and above.

### PROBLEM OF THE INVENTION

Consequently, the present invention is based on the problem of providing an object that is easy to clean, that has a high scratch-resistance, and that has a high-temperature-resistance of for example greater than 350° C., and also to provide a method for producing this object.

### BRIEF DESCRIPTION OF THE INVENTION

This problem is solved by the object in accordance with claim 1. Preferred embodiments of the object are defined in the subclaims 2 to 10 that are also included in combination with one another. Furthermore, the problem is solved by the method in accordance with claim 11. Preferred embodiments of the method are defined in claims 12 to 15 that are also included in combination with one another.

### DETAILED DESCRIPTION OF THE INVENTION

The present invention relates to an object with a high-temperature-resistant omniphobic non-stick coating, comprising: an inorganic substrate, an adhesion-promoting coating that contains amorphic silicon dioxide, and an omniphobic non-stick coating. The adhesion-promoting coating that contains amorphic silicon dioxide is located between the substrate and the omniphobic non-stick coating. It is likewise preferred if the non-stick coating is applied directly to the adhesion-promoting coating.

In accordance with the invention, it is in particular preferred that the adhesion-promoting coating is applied directly to the substrate, in other words that for example a primer is not used. In embodiments, the object consists of an inorganic substrate, an adhesion-promoting coating that contains amorphic silicon dioxide, and an omniphobic non-stick coating.

Surprisingly, it has been found that the specific combination of inorganic substrate, adhesion-promoting coating that contains amorphic silicon dioxide, and omniphobic non-stick coating is easy to clean, has a high scratch-resistance, and possesses a high temperature-resistance.

High temperature resistance in the sense of the present invention means a resistance with respect to temperatures of higher than 350° C., preferably higher than 380° C., and in embodiments up to 400° C. over a time period of at least 24 hours, preferably 48 hours. High temperature resistance in the sense of the present invention also means that after at least ten contamination cycles a cleaning capability of the surface of an accordingly temperature treated sample of burnt-in foodstuffs is provided, in other words that the treated coating does not differ from the original coating.

Omniphobic means both hydrophobic as well as oleophobic, in other words repellent with respect to polar substances such as for example water, and also non-polar substances such as for example organic compounds.

The adhesion-promoting coating in accordance with the invention comprises amorphic silicon dioxide. In particular, the proportion of amorphic silicon dioxide in the coating is 70-100%, preferably 90-99%, in particular preferably 95-98%. In embodiments, the adhesion-promoting coating itself is amorphic. It is preferred that the adhesion-promoting coating is embodied from silicon dioxide. However, crystalline components may also be included such as for example crystalline nanoparticles, inter alia nano particles of crystalline silicon dioxide.

The presence of amorphic silicon dioxide (SiO₂) in the adhesion-promoting coating is surprisingly associated with positive effects in comparison to adhesion-promoting coatings that contain SiOₓ, in which the silicon oxide contains organic residual groups. This can be explained by virtue of the fact that SiO₂ coatings embody a greater adhesion to the inorganic substrate, which is accompanied by an improved temperature resistance. The reason for this lies in the fact that the chemical compatibility of the SiO₂ coating with respect to the inorganic substrate is greater in comparison to SiOₓ coatings. Consequently, the omniphobic non-stick coating may be attached in a stronger manner to the substrate, which in turn increases the scratch-resistance and high-temperature resistance.

The nature of the substrate is not limited in accordance with the invention as long as the substrate is inorganic. The substrate may be planar (such as for example baking sheets or discs) or may possess a three-dimensional shape (such as for example ovens). In embodiments, the organic substrate comprises a material that is selected from the group comprising glass, enamel, metal or ceramic. All types of glass are suitable as substrates such as for example Borofloat glass, soda lime glass or quartz glass. It is preferred that the inorganic substrate is enamel, such as for example an enameled metal surface. In embodiments, the substrate comprises hydroxyl groups on the surface. These may form covalent bonds with the adhesion-promoting coating that contains amorphic silicon dioxide when separating water, which in turn causes an excellent adhesion of the adhesion-promoting coating on the substrate.

The adhesion-promoting coating may be applied using all customary coating methods, for example using fluid coating methods (such as spray methods or immersion methods), where applicable using solvents or dispersing agents, or using deposition methods from the gas phase. In particular, the adhesion-promoting coating is an adhesion-promoting coating that may be obtained by way of a method in which the substrate is coated at atmospheric pressure and that is selected from the group of CVD plasma methods or flame treatment methods. When suitable process parameters are set, it is thus possible to produce an adhesion-promoting coating that contains amorphic silicon dioxide, said adhesion-promoting coating embodying an effective adhesion to the substrate and also to the omniphobic non-stick coating. Furthermore, the instrumental outlay of atmospheric pressure processes is significantly lower than in the case of processes that take place in a vacuum.

The amorphic SiO₂ may be formed in a reactive manner in embodiments during the deposition process for example from precursor substances (in other words precursors). Suitable precursors are not limited in accordance with the invention as long as they are capable of forming SiO₂ during the deposition process. In particular, the adhesion-promoting coating is formed using a siloxane precursor and/or silane precursor, preferably HMDSO (hexamethyldisiloxane), TEOS (tetraethyl orthosilicate), DMS (dimethylsilane) or combinations thereof. An efficient and cost-effective embodiment of an adhesion-promoting coating that contains amorphic silicon dioxide is thus possible in accordance with the present invention.

Suitable process conditions for a CVD plasma method at atmospheric pressure are for example as follows: the ignition of the plasma in a plasma nozzle is provided by way of an electrical discharge. The discharge may be both an arc discharge as well as a barrier discharge. The treatment of the substrate surface may be performed in a relative movement of the nozzle with respect to the substrate surface. In embodiments, the following are possible as setting parameters: 50-200 W, preferably 80-120 W, electrical power; treatment width: 1-20 mm, preferably 5-10mm; traversing speed: 1-10 cm/s, preferably approximately 4-6 cm/s; nozzle distance with respect to the substrate surface: 1-20 mm, preferably approximately 5-10 mm. Compressed air (flow rate: 1-201/min, preferably 5-10 ml/min) may be used as carrier gas. The process gas may be admitted with a flow rate of 1-50 ml/min, preferably 20-40 ml/min.

Suitable process conditions for a flame treatment method at atmospheric pressure are for example as follows: for example propane and/or butane is used as a combustible gas. A mixture of air, combustible gas and precursor gas may for example be ignited in a slot burner head and the colorless region of the flame may move across the substrate surface. The “combustible gas:air” ratio may be for example 101/min:5,0001/min, preferably 501/min:1,0001/min. The traversing speed in embodiments is 1-10 cm/s, preferably approximately 4-6 cm/s. The precursor gas throughflow in embodiments is 1-20 ml/min, preferably 5-15 ml/min. The distance with respect to the substrate surface is for example 10-100 mm, preferably 20-50 mm.

The coating thickness of the adhesion-promoting coating is not critical. In embodiments, the adhesion-promoting coating comprises a coating thickness in the range of below 500 nm, preferably 1-300 nm, more preferably 5-100 nm, further preferably 10-50 nm. A particularly effective adhesion promotion is rendered possible by way of such coating thicknesses with the result that the high temperature resistance is ensured particularly effectively. This may be explained by virtue of the fact that an effective mechanical bonding of the non-stick coating to the substrate is rendered possible by way of this small coating thickness. Furthermore, as a consequence it is possible to obtain transparent coatings that are preferred in accordance with the invention.

The non-stick coating is not limited as long as it comprises omniphobic properties. Omniphobic non-stick coatings are known from the prior art. In particular, the commercially obtainable “Nanoclean” coatings from the company PEMCO are used. The non-stick coating is preferably applied in a wet chemical manner and subsequently dried, wherein the application is preferably provided via a spraying process, immersion process, flooding process, abrasion process or centrifugal casting process.

The non-stick coating preferably comprises a silicon compound. A particularly effective adhesion to the adhesion-promoting coating and to the substrate is thus possible by way of forming covalent bonds, which in turn causes an improved scratch-resistance and high-temperature-resistance.

In preferred embodiments, the non-stick coating is an organically modified network that is deposited via a sol-gel method. An omniphobic non-stick coating may thus be produced, which comprises a particularly effective cleaning capability, scratch-resistance and adhesion with respect to the substrate. In particular, the non-stick coating contains nano particles, which further increases the scratch-resistance.

In particular, an alcoholic solution of a mixture of tetraethyl orthosilicate and methyltriethoxysilane (or another homologs), which may be activated in an acidic or alkaline manner, may be used for the sol-gel method.

It is preferred that the non-stick coating comprises fluorochemical compounds, in particular preferably fluorochemical silanes and/or siloxanes such as for example 1H, 1H, 2H, 2H-perfluorooctyltriethoxysilane or its homologs. It is possible by way of incorporating such fluorochemical compounds to achieve particularly effective omniphobic effects.

The coating thickness of the non-stick coating is not limited in accordance with the invention. In embodiments, the non-stick coating comprises a coating thickness in the range of less than 100 nm, preferably 2-50 nm, more preferably 5-20 nm, further preferably 10-15 nm. As a consequence, a particularly effective high-temperature-resistance is rendered possible. Furthermore, as a consequence it is possible to obtain transparent coatings that are preferred in accordance with the invention.

In embodiments, the entire coating thickness, in other words the sum of the adhesion-promoting coating and non-stick coating is 1-600 nm, preferably 10-500 nm, more preferably 20-400 nm.

The non-stick coating is omniphobic and in particular represents a contact angle with respect to a polar substance such as water of 90° or more and/or a contact angle with respect to non-polar substances such as methylene iodide, ethylene glycol, thiodiglycol or diiodomethane of 70° or more. These requirements of the contact angle are preferably maintained in the case of a temperature treatment at 350° C. for 24 hours, preferably in the case of a temperature treatment of 350° C. for 48 hours.

The object in embodiments possesses a surface energy of 25 mN/m or less, preferably 20 mN/m or less, wherein these requirements for the surface energy preferably remain unchanged after a temperature treatment at 350° C. for 24 hours, further preferably at 350° C. for 48 hours.

The object is preferably selected from household appliances or kitchen appliances such as for example glass control panels, door panes, inspection glasses, extractor hoods, or (kitchen) cupboard windows. Furthermore, the object may be a kitchen accessory such as for example baking sheets, pans, pots, baking dishes, cooking utensils, kettles, side parts or lid parts of hobs or working surfaces for example, lamp coverings or a part of cooking appliances such as ovens or microwave appliances for example. In particular, hot plates, glass ceramic hobs, ovens, door inner panes, chromed accessory parts or parts of stainless steel in or on the oven interior such as for example grillages, roasting spit rods, receiving frames for baking sheets, telescopic pull outs, vapor strips and/or air discharging apertures are suitable as parts of cooking appliances. In particular, the object is an object that is heated and/or comes into contact with heated foodstuffs. It is particularly preferred that the object is a baking sheet or a pan.

The object may be coated entirely or only in part. If the object is coated in part, the coating is preferably located on the part of the object that is heated and/or comes into contact with heated foodstuffs.

Furthermore, the present invention relates to a method for producing an object with a high-temperature-resistant non-stick coating. The method comprises the steps: providing an inorganic substrate, applying an adhesion-promoting coating that contains amorphic silicon dioxide to the substrate, applying an omniphobic non-stick coating to the adhesion-promoting coating. It is possible using this method to produce an object that is easy to clean, comprises a high scratch-resistance and that comprises a high-temperature-resistance at temperatures of for example greater than 350° C.

It is preferred that a preceding procedure of cleaning the substrate is performed by means of washing using aqueous (for example acidic or alkaline) cleaning agents or organic cleaning agents. In this case, possibly present coarse dirt such as for example dust, oils, fat, fingerprints etc. are removed. The adhesion may thus be increased.

In embodiments, the method is a method in which, when the adhesion promoting coating is applied to the substrate, covalent bonds are formed by way of condensation reaction of hydroxyl groups of the substrate surface and reactive groups of the adhesion promoter. The adhesion may thus be further increased.

In particular, it is possible during the method to apply the adhesion-promoting coating to the substrate at atmospheric pressure, wherein the method is selected from the group of CVD plasma methods or flame treatment methods. In a preferred embodiment, the adhesion-promoting coating is applied using a siloxane precursor and/or silane precursor, in particular HMDSO, TEOS, DMS or combinations thereof. It is preferred that the non-stick coating is applied by way of wet chemical deposition via a sol-gel method and subsequent drying process, wherein the application is preferably performed via a spraying process, immersion process, flooding process, abrasion process or centrifugal casting process.

This and further embodiments of the method and its advantages are described in detail in relation to the object in accordance with the invention and are not further explained here.

### EXAMPLES

The following measuring methods have been used to determine the parameter coating thickness, contact angle and surface energy:

Spectral ellipsometry is a measuring method with which the dielectric material properties (complex permittivity or real part or imaginary part of the complex refractive index) and also the coating thickness of thin coatings or coating systems may be determined. The ellipsometry determines the change of the polarization state of light during reflection (or transmission) on the sample. Statements with regard to the thickness and refractive index of the applied coating are included in the result of the measurements and by way of adapting a coating model.

The coating thickness was measured by means of spectral ellipsometry using a spectral ellipsometer SE850 from the company Sentech. In this case, measurements are taken in the wavelength range of 350-820 nm and on the basis of a Cauchy model approach.

The contact angle has been measured using a contact angle measuring device OCA 15 plus the company Dataphysics in accordance with the generally known contact angle measuring methods according to Owens, Wendt, Rabel and Kaelble.

The contact angle is referred to as the edge angle and is the angle that forms a fluid droplet on the surface of a solid material to a surface. The equilibrium of forces of a fluid droplet that lies on the surface is provided by way of the surface tensions of the fluid and the solid body and also the interfacial tension between the two media. This equilibrium determines whether a fluid droplet spreads on a surface (in other words moistens the surface well) or whether the fluid remains unchanged as droplets (moistens the surface poorly). The surface tension differs according to the underlying interaction mechanisms between the molecules between polar and dispersal interactions. The polar forces have their cause in different electronegativities of the atoms of a molecule, from which permanent dipoles are provided. The dispersion forces are provided by way of temporarily asymmetrical charge distributions and are consequently present between all molecules. The surface tension is provided from the sum of the polar and the dispersal proportion. The procedure of determining the surface tension of a solid body is performed by way of measuring the different contact angle that the different test fluids leave on the solid body. The method according to Owens, Wendt, Rabel and Kaelble is a standard method for calculating the free surface energy of a solid body from the contact angle with multiple fluids. The free surface energy is divided in this case into a polar proportion and into a dispersal proportion. During the tests, measurements of ten droplets per sample were performed, wherein the result is the arithmetic average value of the measurements. Water, methylene iodide, ethylene glycol, thiodiglycol and diiodomethane are used as testing fluids in order to determine the surface tensions.

The surface energy has been determined using the software SCA20 from the company Dataphysics on the basis of the contact angle measuring data.

### Example 1

An enameled baking sheet was used as a substrate, said baking sheet being pre-cleaned by way of washing and was subsequently dried.

An adhesion-promoting coating that contains amorphic silicon dioxide was applied to the substrate via a CVD plasma process at atmospheric pressure. In this case, a plasma was ignited in a plasma nozzle by way of an electrical arc discharge and the surface was treated in a relative movement of the nozzle with respect to the substrate surface. Setting parameters were: approximately 100 Watt electrical power, approximately 10 mm treatment width, approximately 5 cm/s traversing speed, approximately 10 mm nozzle distance with respect to the substrate surface, approximately 5 bar compressed air (101/min). HMDSO was used as a process gas (flow rate: approximately 30 ml/min.). The coating thickness of the transparent adhesion-promoting coating was under 200 nm.

Subsequently, the surface that is coated with the adhesion promoter was provided with an omniphobic non-stick coating. In this case, a commercially obtainable “Nanoclean” coating from the company PEMCO is sprayed on using a spray pistol in accordance with the manufacturer specifications. The process conditions were as follows: pressure: 2.5 bar, distance 15 cm, 2 runs, drying at room temperature. The entire coating thickness of the transparent coating that is obtained (adhesion promoter +omniphobic non-stick coating was less than 500 nm.

The properties of the coated baking sheet after the production were as follows: contact angle: greater than 90° (water); contact angle greater than 70° (methylene iodide); surface energy: less than 20 mN/m. After storing the coated baking sheet for 24 hours at 350° C. the results were as follows: contact angle: greater than 90° (water); contact angle greater than 70° (methylene iodide); surface energy: less than 20 mN/m.

### Example 2

The production of a coated baking sheet is performed in a similar manner to example 1 with the difference that the adhesion-promoting coating that contains amorphic silicon dioxide was applied by means of a flame treatment. In this case, a gas mixture (air, combustible gas and HMDSO precursor) was ignited in a slot burner head and the colorless region of the flame is moved across the substrate surface. The combustible gas-air ratio was 50/1,0001/min, the traversing speed 5 cm/s, the gas throughflow 10 ml/min (15% HMDSO, the distance from the substrate surface was 30 mm.

The coating thickness achieved was similar to example 1. The coated baking sheet both directly after production as well as after being stored for 24 hours at 350° C. had a contact angle of greater than 90° (water) and a contact angle of greater than 70° (methylene iodide) and also a surface energy of less than 20 mN/m.

### Comparative Example

A coated baking sheet similar to the examples 1 and 2 is produced as a comparative example with the difference that in lieu of the adhesion-promoting coating that contains amorphic silicon dioxide, an SiOₓ coating was applied. In this case, the substrate was silanized by way of flame treatment prior to applying the “Nanoclean” coating in accordance with the production specifications from the company PEMCO.

The baking sheet that is coated in this manner had a surface energy of 20 mN/m directly after production. However, the surface energy after being stored for 24 hours at 350° C. increased to 48 mN/m, in other words the temperature resistance was lower. As a consequence, the cleaning capability of the baking sheet deteriorated in comparison to the examples 1 and 2.

1-15 (canceled)

16. An object having a high-temperature resistance, said object comprising:
an inorganic substrate;
an omniphobic non-stick coating; and
an adhesion-promoting coating containing amorphic silicon dioxide and located between the inorganic substrate and the omniphobic non-stick coating.

17. The object of claim 16, wherein the inorganic substrate comprises a material selected from the group consisting of glass, enamel, metal, and ceramic.

18. The object of claim 16, wherein the inorganic substrate comprises enamel.

19. The object of claim 16, wherein the adhesion-promoting coating is coated upon the substrate at atmospheric pressure through a CVD plasma method or flame treatment method.

20. The object of claim 16, wherein the adhesion-promoting coating is formed using at least one precursor selected from the group consisting of a siloxane precursor and a silane precursor.

21. The object of claim 20, wherein the at least one precursor is HMDSO, TEOS, DMS, or any combination thereof.

22. The object of claim 16, wherein the non-stick coating comprises a silicon compound.

23. The object of claim 16, wherein the non-stick coating is an organically modified network that is deposited via a sol-gel method.

24. The object of claim 16, wherein the non-stick coating comprises fluorochemical compounds, preferably fluorochemical silanes and/or siloxanes.

25. The object of claim 16, wherein the adhesion-promoting coating comprises a coating thickness in a range of below 500 nm, preferably 1-300 nm, more preferably 5-100 nm, further preferably 10-50 nm, wherein the coating thickness is measured by means of spectral ellipsometry.

26. The object of claim 16, wherein the non-stick coating comprises a coating thickness in a range of less than 100 nm, preferably 2-50 nm, more preferably 5-20 nm, further preferably 10-15 nm, wherein the coating thickness is measured by means of spectral ellipsometry.

27. The object of claim 16, wherein the non-stick coating has a contact angle of 90° or more with respect to water and/or a contact angle of 70° or more with respect to methylene iodide, preferably after a temperature treatment at 350° C. for 24 hours, wherein the contact angle is measured using a contact angle measuring device in accordance with a contact angle measuring method according to Owens, Wendt, Rabel and Kaelble.

28. The object of claim 16, wherein the non-stick coating has a surface energy of 25 mN/m or less, preferably 20 mN/m or less, preferably after a temperature treatment at 350° C. for 24 hours, wherein the surface energy is determined on the basis of contact angle measuring data according to Owens, Wendt, Rabel and Kaelble.

29. A method for producing an object having a high-temperature resistance, said method comprising:
applying an adhesion-promoting coating that contains amorphic silicon dioxide to an inorganic substrate; and
applying an omniphobic non-stick coating to the adhesion-promoting coating.

30. The method of claim 29, wherein, when the adhesion-promoting coating is applied to the inorganic substrate, covalent bonds are formed by way of condensation reaction of hydroxyl groups of a surface of the inorganic substrate and reactive groups of the adhesion-promoting coating.

31. The method of claim 29, wherein the adhesion-promoting coating is applied to the inorganic substrate at atmospheric pressure via a method selected from the group consisting of CVD plasma method and flame treatment method.

32. The method of claim 29, wherein the adhesion-promoting coating is applied using at least one precursor selected from the group consisting of siloxane precursor and silane precursor.

33. The method of claim 32, wherein the at least one precursor is HMDSO, TEOS, DMS, or any combination thereof.

34. The method of claim 29, wherein the non-stick coating is applied by way of wet chemical deposition via a sol-gel method and a subsequent drying process.

35. The method of claim 29, wherein the non-stick coating is applied by a spraying process, immersion process, flooding process, abrasion process or centrifugal casting process.
